(19) United States
(12) Patent Application Publication
(10) Pub. No.: US 2026/0343800 A1
(43) Pub. Date: Oct. 29, 2026

(54) CPU Liquid Cooling Heat Dissipation Device with Dual-Screen Display Function

(71) Applicant: Shanghai TRYX Technology Co., Ltd., Shanghai (CN)

(72) Inventors: Hang CUI, Shanghai (CN); Xingzhe WANG, Shanghai (CN); Xiaoyang WANG, Shanghai (CN)

(21) Appl. No.: 19/435,154

(22) Filed: Dec. 29, 2025

(30) Foreign Application Priority Data
Apr. 28, 2025 (CN) 202520825186.8

(51) Int. Cl. H05K 7/20; H05K 5/00

(52) U.S. Cl. CPC H05K 7/20263; H05K 5/0018; H05K 7/20272

(57) ABSTRACT

The present invention relates to a CPU liquid cooling heat dissipation device with a dual-screen display function. The heat dissipation device is constituted by three mutually perpendicular planar components, comprising a first display screen assembly, a second display screen assembly, and a quick-detachable appearance component. The first display screen assembly has a liquid cooling heat dissipation component fixedly installed thereon. The first display screen assembly, the second display screen assembly, and the quick-detachable appearance component are nested, interpenetrated, and integrally formed with each other. By adopting the CPU liquid cooling heat dissipation device with the dual-screen display function of the present technical solution, a naked-eye 3D effect can be achieved through the mutually perpendicular combination of the two screens coupled with specially designed images. Compared to the display method of a single liquid cooler screen, the present invention more diversely designs the screen display effect, differing from the conventional design of previous liquid coolers, thereby increasing the playability of DIY computers.

### CROSS REFERENCE OF RELATED APPLICATIONS

The present application claims the priority of the Chinese utility model patent application which application number is 202520825186.8 filed Apr. 28, 2025, and the contents of which are hereby incorporated into this application by reference.

### FIELD OF TECHNOLOGY

The present technical solution relates to the field of liquid cooling heat dissipators, and more particularly to CPU liquid cooling heat dissipators, specifically to a CPU liquid cooling heat dissipation device with a dual-screen display function.

### BACKGROUND

Currently, products of liquid cooling heat dissipators with screens are gradually increasing in the market. These screens are mainly used to display system status, temperature, custom images, or animations, etc., and by providing high-resolution screens and rich functions, they aim to meet users' needs for system monitoring and personalization.

However, as shown in FIGS. 1 and 2, most existing liquid cooling heat dissipators with screens have only one screen parallel to the bottom surface of the CPU. After the pump head is installed on the CPU, a plastic component embedded with an LCD screen covers the pump. While this can fulfill the screen display function, the display effect is extremely singular, thus lacking the diversified playability brought by visual impact. Consequently, it cannot better cater to the usage demands of the market and consumers, and is also not conducive to product iteration and innovation.

### SUMMARY OF THE INVENTION

The object of the present invention is to overcome the shortcomings in the aforementioned prior art and to provide a CPU liquid cooling heat dissipation device with a dual-screen display function.

To achieve the above object, the CPU liquid cooling heat dissipation device with a dual-screen display function according to the present invention is specifically as follows:

The CPU liquid cooling heat dissipation device with a dual-screen display function, the main feature of which is that the heat dissipation device is constituted by three mutually perpendicular planar components, comprising a first display screen assembly, a second display screen assembly, and a quick-detachable appearance component, wherein the first display screen assembly has a liquid cooling heat dissipation component fixedly installed thereon, and wherein the first display screen assembly, the second display screen assembly, and the quick-detachable appearance component are nested, interpenetrated, and integrally formed with each other.

Preferably, the quick-detachable appearance component is disposed at the bottom of the heat dissipation device, the first display screen assembly and the second display screen assembly are adjacent to each other, and both are vertically and perpendicularly connected to the quick-detachable appearance component.

Preferably, the quick-detachable appearance component is a detachable structure comprising two single sides, wherein one single side is a first reflective surface, the other single side is a second reflective surface, and a magnetic component is disposed between the two single sides, and wherein the quick-detachable appearance component is entirely installed on a plastic component embedded with magnets, thereby achieving magnetic fixation between the quick-detachable appearance component and the plastic component.

More preferably, when the first reflective surface contacts the plastic component, an outwardly displayed surface of the quick-detachable appearance component is the second reflective surface; when the second reflective surface contacts the plastic component, the outwardly displayed surface of the quick-detachable appearance component is the first reflective surface.

Preferably, the heat dissipation device further comprises an L-shaped first plastic base, wherein the first display screen assembly is fixed on a vertical plane of the first plastic base, and the plastic component is fixed on a horizontal plane of the first plastic base.

Preferably, a metal component is fixedly disposed at the bottom of the horizontal plane of the first plastic base, and the metal component and the quick-detachable appearance component are fixed together by screwing.

Preferably, the second display screen assembly is disposed on a metal component and is entirely installed on a side of the first plastic base.

Preferably, the liquid cooling heat dissipation component comprises a water block and an upper plastic housing of the liquid cooler, wherein the water block is installed on the upper plastic housing of the liquid cooler, and the entirety is installed on an outer side of the vertical plane of the first plastic base.

Preferably, magnets are installed in holes of the upper plastic housing of the liquid cooler, and the entire liquid cooling heat dissipation component is magnetically fixed onto the vertical plane of the first plastic base via positioning pins.

By adopting the CPU liquid cooling heat dissipation device with the dual-screen display function of the present invention, a naked-eye 3D effect can be achieved through the mutually perpendicular combination of the two screens coupled with specially designed images. Simultaneously, under the reflection of the single-sided mirror-silver Mylar, an effect similar to holographic projection can be attained, thereby more diversely designing the screen display effect, enhancing visual expression, and increasing the playability of DIY computers.

### BRIEF DESCRIPTION OF THE DRAWINGS

FIG. 1 is a reference diagram showing the design effect of a liquid cooling heat dissipator in the prior art.

FIG. 2 is another reference diagram showing the design effect of a liquid cooling heat dissipator in the prior art.

FIG. 3 is a schematic diagram of the CPU liquid cooling heat dissipation device with a dual-screen display function according to the present invention.

FIG. 4 is a schematic diagram showing the installation of the first display screen assembly according to the present invention.

FIG. 5 is a schematic diagram showing the installation of the second display screen assembly according to the present invention.

FIG. 6 is a structural schematic diagram of the quick-detachable appearance component according to the present invention.

FIG. 7 is a structural schematic diagram of the quick-detachable appearance component and the plastic component according to the present invention.

FIG. 8 is an installation schematic diagram after combining the quick-detachable appearance component with the plastic component according to the present invention.

FIG. 9 is a bottom structural schematic diagram of the first plastic base according to the present invention.

FIG. 10 is a schematic diagram showing the installation of the liquid cooling heat dissipation component according to the present invention.

FIG. 11 is another schematic diagram showing the installation of the liquid cooling heat dissipation component according to the present invention.

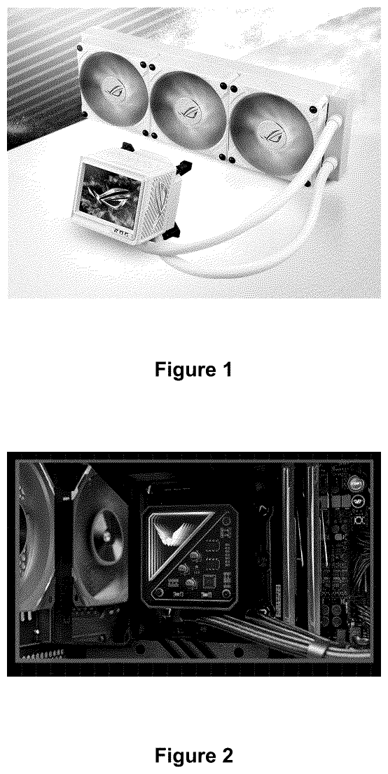

### REFERENCE NUMBERS IN FIGURES

1 First display screen assembly
2 Second display screen assembly
2-1 Metal component
3 Quick-detachable appearance component
3-1 First reflective surface
3-2 Second reflective surface
3-3 Magnetic component
3-4 Plastic component
4 Liquid cooling heat dissipation component
4-1 Water block
4-2 Upper plastic housing of the liquid cooler
5 First plastic base
5-1 Vertical plane
5-2 Horizontal plane
5-3 Metal component

### DETAILED DESCRIPTION

In order to be able to understand the technical content of the present invention more clearly, the following embodiments are specifically described.

Before detailing the embodiments according to the present invention, it should be noted that, in the following context, the term “comprising”, “including”, or any other variation thereof is intended to cover non-exclusive inclusion, such that a process, method, article, or device comprising a series of elements includes not only those elements, but also other elements not explicitly listed, or elements inherent to such process, method, article, or device.

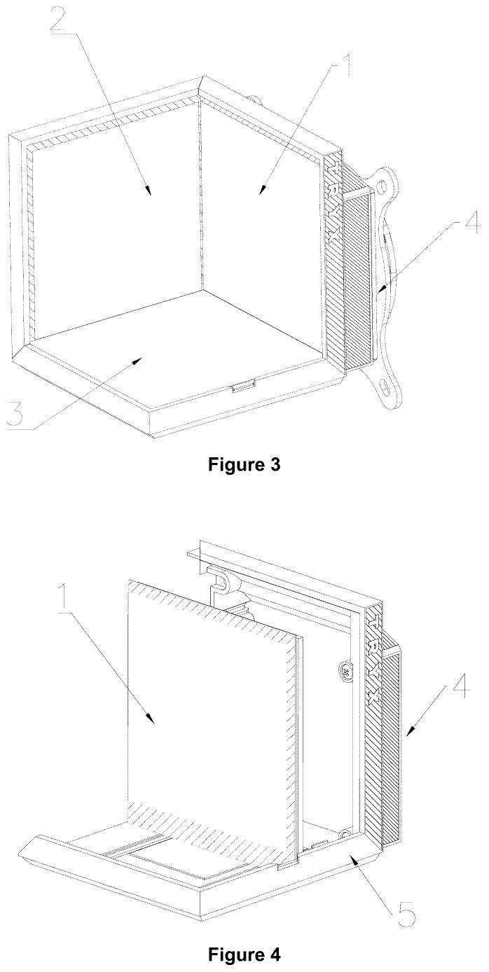

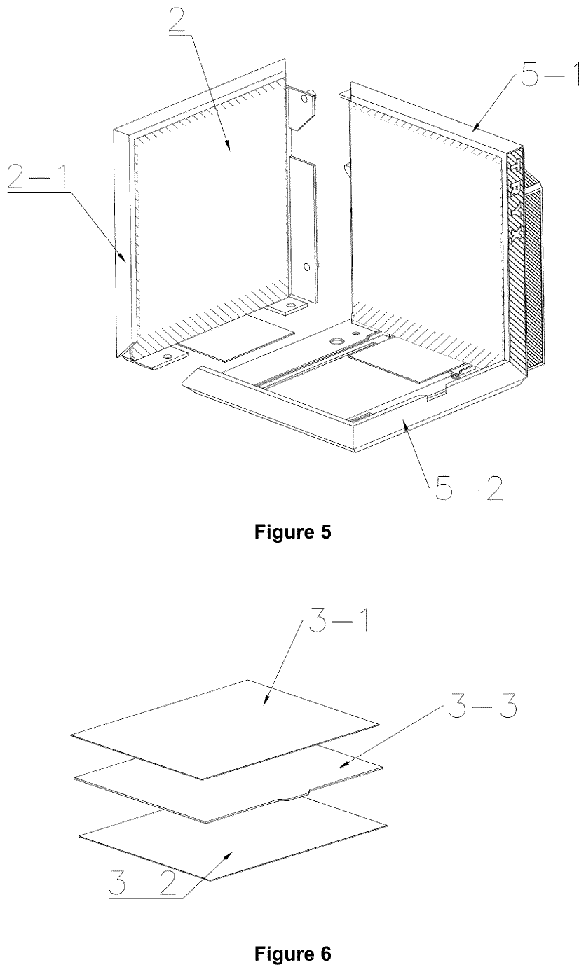

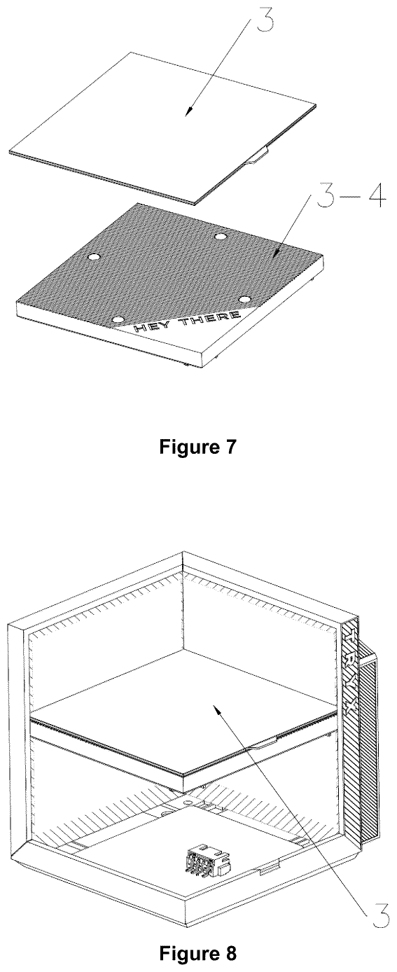

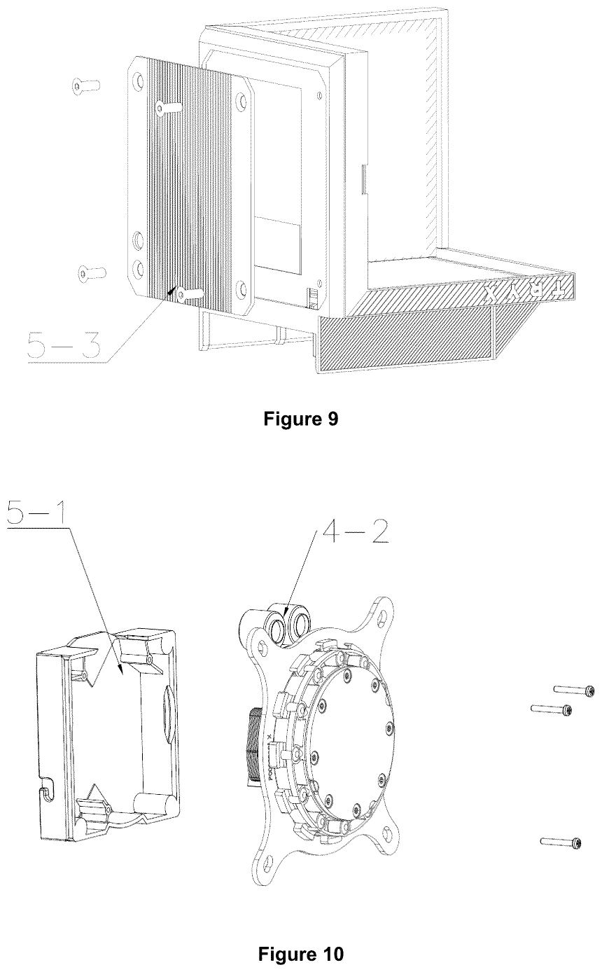

As shown in FIG. 3. The CPU liquid cooling heat dissipation device with dual-screen display function according to the present invention comprises a heat dissipation device constituted by three mutually perpendicular planar components, including a first display screen assembly 1, a second display screen assembly 2, and a quick-detachable appearance component 3. The first display screen assembly 1 has a liquid cooling heat dissipation component 4 fixedly installed thereon. These three planar components are nested and interpenetrated with each other and, in practical applications, can be integrally formed by means such as screw fastening.

As a preferred embodiment of the present invention, the quick-detachable appearance component 3 is disposed at the bottom of the heat dissipation device. The first display screen assembly 1 and the second display screen assembly 2 are adjacent to each other and are both vertically and perpendicularly connected to the quick-detachable appearance component 3. As a preferred embodiment of the present invention, the quick-detachable appearance component 3 is a detachable structure comprising two single sides. One single side is a first reflective surface 3-1, and the other single side is a second reflective surface 3-2. A magnetic component 3-3 is disposed between the two single sides. The quick-detachable appearance component 3 is entirely installed on a plastic component 3-4 embedded with magnets, thereby achieving magnetic fixation between the quick-detachable appearance component 3 and the plastic component 3-4.

As a preferred embodiment of the present invention, when the first reflective surface 3-1 contacts the plastic component 3-4, the outwardly displayed surface of the quick-detachable appearance component 1 is the second reflective surface 3-2. When the second reflective surface 3-2 contacts the plastic component 3-4, the outwardly displayed surface of the quick-detachable appearance component 1 is the first reflective surface 3-1, thereby achieving a reversible configuration function.

As a preferred embodiment of the present invention, the heat dissipation device further comprises an L-shaped first plastic base 5. The first display screen assembly 1 is fixed on the vertical plane 5-1 of the first plastic base 5. The plastic component 3-4 is fixed on the horizontal plane 5-2 of the first plastic base 5.

As a preferred embodiment of the present invention, a metal component 5-3 is fixedly disposed at the bottom of the horizontal plane 5-2 of the first plastic base 5. The metal component 5-3 and the quick-detachable appearance component 3 are fixed together by screwing.

As a preferred embodiment of the present invention, the second display screen assembly 2 is disposed on a metal component 2-1 and is entirely installed on the side of the first plastic base 5. In practical applications, this metal component 2-1 can be an aluminum component. As a preferred embodiment of the present invention, the liquid cooling heat dissipation component 4 comprises a water block 4-1 and an upper plastic housing of the liquid cooler 4-2. The water block 4-1 is installed on the upper plastic housing of the liquid cooler 4-2, and the entirety is installed on the outer side of the vertical plane of the first plastic base 5.

As a preferred embodiment of the present invention, magnets are installed in the holes of the upper plastic housing of the liquid cooler 4-2. The entire liquid cooling heat dissipation component is magnetically fixed onto the vertical plane of the first plastic base 5 via positioning pins.

As shown in FIG. 3, the CPU liquid cooling heat dissipation device with dual-screen display function of the present invention adopts three mutually perpendicular planar components to form an integral product. It is assembled with the liquid cooling heat dissipation component 4 by nesting plastic components. Among the three mutually perpendicular planar components, two are display screen assemblies, and the bottom one is the quick-detachable appearance component 3. The quick-detachable appearance component 3 entirely adheres to the plastic component 3-4. These three planar modules are nested and interpenetrated and, in practical applications, can be integrated into one whole by means such as screw fastening. This combined screen approach, along with the quick-detachable appearance component that complements the screens, significantly enhances the playability of the liquid cooler's screen, breaking the single display effect of a conventional LCD flat screen.

As a preferred embodiment of the present invention, one side of the quick-detachable appearance component 3 is the first reflective surface 3-1, and the other side is the second reflective surface 3-2. This component can reflect the images from the two display screens in real time, achieving a unique combined visual expression.

The installation method of the CPU liquid cooling heat dissipation device with dual-screen display function according to the present technical solution is further explained below in combination with specific usage scenarios:

As shown in FIG. 4, the first display screen assembly 1 is attached via double-sided tape to the vertical plane 5-1 of the first plastic base 5 to complete the installation of the first screen. The second display screen assembly 2 is pasted onto an aluminum component to complete the installation of the second screen. Then, the second display screen assembly 2 and the aluminum component are inserted sideways into the first plastic base 5 as a whole and fixed by screwing.

In practical applications, the magnetic component 3-3 provided on the quick-detachable appearance component 3 is an iron strip. The first reflective surface 3-1 is pasted on the upper side of the iron strip, and the second reflective surface 3-2 is pasted on the lower side of the iron strip, thereby forming the installation of the quick-detachable appearance component 3. Meanwhile, the material of the reflective surface can be selected accordingly based on actual conditions to achieve a better display effect.

Furthermore, the quick-detachable appearance component 3 assembled in the previous step is pasted onto the plastic component 3-4 and fixed together by magnetic attraction using the magnets embedded in the plastic component 3-4, completing the installation.

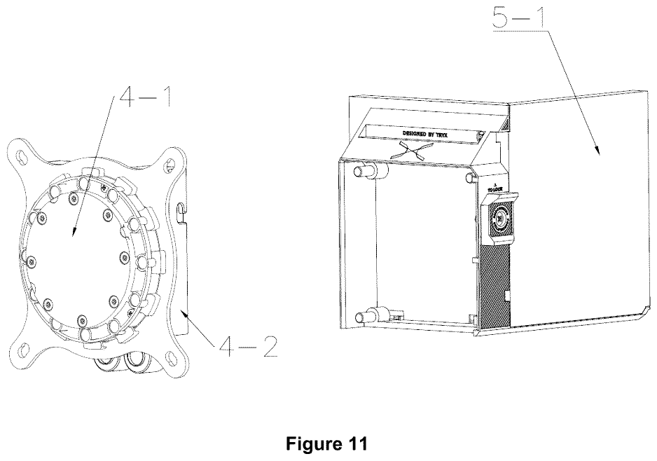

After the quick-detachable appearance component 3 is pasted onto the plastic component 3-4, the two form an integral unit, which is placed on the horizontal plane 5-2 of the first plastic base 5. Since the plastic component 3-4 has four embedded nuts at corresponding hole positions, the side aluminum component is then placed against the first plastic base 5. Using four screws, the second display screen assembly 2, the quick-detachable appearance component 3, the plastic component 3-4, and the first plastic base 5 are all fastened together. In practical applications, as shown in FIG. 10, three screws are used to fasten the water block 4-1 and the upper plastic housing of the liquid cooler 4-2 together, forming a liquid cooling heat dissipation component 4. Magnets corresponding to the screw positions are pre-embedded in the upper plastic housing of the liquid cooler 4-2.

As shown in FIG. 11, the three positioning pins pre-embedded at the bottom of the first plastic base 5 and the three magnets embedded in the liquid cooling heat dissipation component 4 attract each other, completing the assembly and fixation of the two components. It is understandable that the aforementioned pasting methods, screw fastening, magnetic attraction methods, as well as the types and quantities of corresponding components are only illustrative examples here. In practical applications, the connection relationships and interaction relationships between the various connecting technical features of the CPU liquid cooling heat dissipation device with dual-screen display function according to the present technical solution are not limited to the contents listed above. Other similar or analogous arrangement methods, positional relationships, and quantities shall be included within the scope of protection claimed by the present technical solution and will not be reiterated here. By adopting the CPU liquid cooling heat dissipation device with dual-screen display function of the present invention, through the combination of two mutually perpendicular screens coupled with specially designed images, a naked-eye 3D effect can be achieved. Simultaneously, under the reflection of the quick-detachable appearance component, an effect similar to holographic projection can be attained, thereby diversifying the screen display effect design, enhancing visual expression, and increasing the playability of DIY computers. In this specification, the present invention has been described with reference to its specific embodiments. However, it is apparent that various modifications and changes can still be made without departing from the spirit and scope of the present invention. Therefore, the description and drawings should be regarded as illustrative rather than restrictive.

1. A CPU liquid cooling heat dissipation device with a dual-screen display function, characterized in that the heat dissipation device is constituted by three mutually perpendicular planar components, comprising a first display screen assembly (1), a second display screen assembly (2), and a quick-detachable appearance component (3), wherein the first display screen assembly has a liquid cooling heat dissipation component (4) fixedly installed thereon, and wherein the first display screen assembly (1), the second display screen assembly (2), and the quick-detachable appearance component (3) are nested, interpenetrated, and integrally formed with each other.

2. The CPU liquid cooling heat dissipation device with a dual-screen display function according to claim 1, characterized in that the quick-detachable appearance component (3) is disposed at a bottom of the heat dissipation device, the first display screen assembly (1) and the second display screen assembly (2) are adjacent to each other, and both are vertically and perpendicularly connected to the quick-detachable appearance component (3).

3. The CPU liquid cooling heat dissipation device with a dual-screen display function according to claim 1, characterized in that the quick-detachable appearance component (3) is a detachable structure comprising two single sides, wherein one single side is a first reflective surface (3-1), the other single side is a second reflective surface (3-2), and a magnetic component (3-3) is disposed between the two single sides, and wherein the quick-detachable appearance component (3) is entirely installed on a plastic component (3-4) embedded with magnets, thereby achieving magnetic fixation between the quick-detachable appearance component (3) and the plastic component (3-4).

4. The CPU liquid cooling heat dissipation device with a dual-screen display function according to claim 3, characterized in that:
when the first reflective surface (3-1) contacts the plastic component (3-4), an outwardly displayed surface of the quick-detachable appearance component (1) is the second reflective surface (3-2);
when the second reflective surface (3-2) contacts the plastic component (3-4), the outwardly displayed surface of the quick-detachable appearance component (1) is the first reflective surface (3-1).

5. The CPU liquid cooling heat dissipation device with a dual-screen display function according to claim 3, characterized in that the heat dissipation device further comprises an L-shaped first plastic base (5), wherein the first display screen assembly (1) is fixed on a vertical plane (5-1) of the first plastic base (5), and the plastic component (3-4) is fixed on a horizontal plane (5-2) of the first plastic base (5).

6. The CPU liquid cooling heat dissipation device with a dual-screen display function according to claim 5, characterized in that a metal component (5-3) is fixedly disposed at a bottom of the horizontal plane (5-2) of the first plastic base (5), and the metal component (5-3) and the quick-detachable appearance component (3) are fixed together by screwing.

7. The CPU liquid cooling heat dissipation device with a dual-screen display function according to claim 5, characterized in that the second display screen assembly (2) is disposed on a metal component (2-1) and is entirely installed on a side of the first plastic base (5).

8. The CPU liquid cooling heat dissipation device with a dual-screen display function according to claim 5, characterized in that the liquid cooling heat dissipation component (4) comprises a water block (4-1) and an upper plastic housing of the liquid cooler (4-2), wherein the water block (4-1) is installed on the upper plastic housing of the liquid cooler (4-2), and the entirety is installed on an outer side of the vertical plane of the first plastic base (5).

9. The CPU liquid cooling heat dissipation device with a dual-screen display function according to claim 8, characterized in that magnets are installed in holes of the upper plastic housing of the liquid cooler (4-2), and the entire liquid cooling heat dissipation component is magnetically fixed onto the vertical plane of the first plastic base (5) via positioning pins.
